(19) United States
(12) Patent Application Publication
(10) Pub. No.: US 2017/0040340 A1
(43) Pub. Date: Feb. 9, 2017

(54) SEMICONDUCTOR MEMORY DEVICE AND METHOD FOR MANUFACTURING THE SAME

(71) Applicant: Kabushiki Kaisha Toshiba, Tokyo (JP)

(72) Inventors: Katsuaki NATORI, Yokkaichi (JP); Masayuki TANAKA, Yokkaichi (JP); Keiichi SAWA, Yokkaichi (JP); Tetsuya KAI, Yokkaichi (JP); Shinji MORI, Yokkaichi (JP)

(21) Appl. No.: 15/298,807

(22) Filed: Oct. 20, 2016

Related U.S. Application Data
(62) Division of application No. 14/613,412, filed on Feb. 4, 2015.
(60) Provisional application No. 62/044,556, filed on Sep. 2, 2014.

(51) Int. Cl. H01L 27/115; H01L 21/02; H01L 23/528; H01L 21/441; H01L 29/24; H01L 29/45

(52) U.S. Cl. CPC H01L 27/11582; H01L 29/24; H01L 29/45; H01L 23/528; H01L 27/11556; H01L 21/441; H01L 21/02244; H01L 21/02565

(57) ABSTRACT

According to one embodiment, a semiconductor memory device includes a stacked body; a semiconductor body; and charge storage film. The stacked body includes the plurality of electrode layers separately stacked each other. The semiconductor body is provided in the stacked body and extends in a stack direction of the stacked body and includes an oxide semiconductor. The charge storage film is provided between the semiconductor body and the plurality of electrode layers.

This application is based upon and claims the benefit of priority from U.S. Provisional Patent Application 62/044,556 field on Sep. 2, 2014; the entire contents of which are incorporated herein by reference.

### FIELD

Embodiments described herein relate generally to a semiconductor memory device and a method for manufacturing the same.

### BACKGROUND

A memory device of 3-dimensional structure has been proposed. The memory device includes a stacked body having a plurality of electrode layers functioning as a control gate in a memory cell stacked via an insulating layer and having a memory hole formed, and a silicon body serving as a channel provided on a side wall of the memory hole via a charge storage film.

With high integration of memory cells, increase of a resistance may be caused.

### BRIEF DESCRIPTION OF THE DRAWINGS

FIG. 1 is a schematic perspective view of a memory cell array of an embodiment;

FIG. 2 is a schematic cross-sectional view of a memory string of the embodiment;

FIG. 3 is an enlarged schematic cross-sectional view of a portion of a pillar unit of the embodiment;

FIG. 4A to FIG. 6B are schematic cross-sectional views showing a method for manufacturing a semiconductor memory device of the embodiment;

FIG. 7 and FIG. 8 are schematic cross-sectional views of a memory string of another embodiment;

FIG. 9 is a schematic perspective view of another memory cell array of the embodiment;

FIG. 10 is a schematic cross-sectional view of a memory string of still another embodiment;

FIG. 11A to FIG. 18B are schematic cross-sectional views showing a method for manufacturing a semiconductor memory device of a still another embodiment;

FIG. 19 is a schematic perspective view of a memory cell array of still another example of the embodiment;

FIG. 20 is a schematic plan view of a memory cell array of still another example of the embodiment; and

FIG. 21 is a schematic cross-sectional view of a memory cell array of still another example of the embodiment.

### DETAILED DESCRIPTION

According to one embodiment, a semiconductor memory device includes a stacked body; a semiconductor body; and charge storage film. The stacked body includes the plurality of electrode layers separately stacked each other. The semiconductor body is provided in the stacked body and extends in a stack direction of the stacked body and includes an oxide semiconductor. The charge storage film is provided between the semiconductor body and the plurality of electrode layers.

Various embodiments will be described hereinafter with reference to the accompanying drawings. In the respective drawings, similar components are marked with same reference numerals.

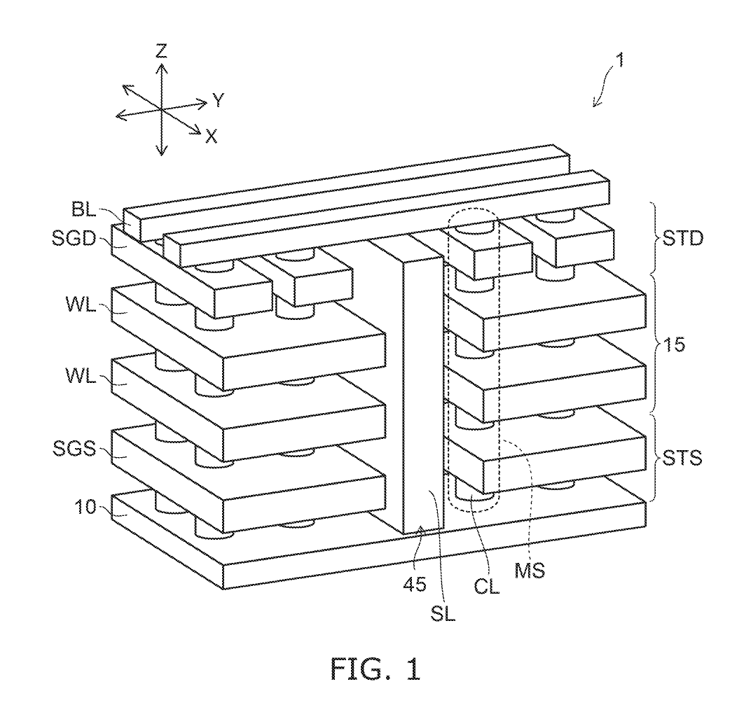

FIG. 1 is a schematic perspective view of a memory cell array 1 of an embodiment. In FIG. 1, insulating layers are omitted for convenience of viewing the drawing.

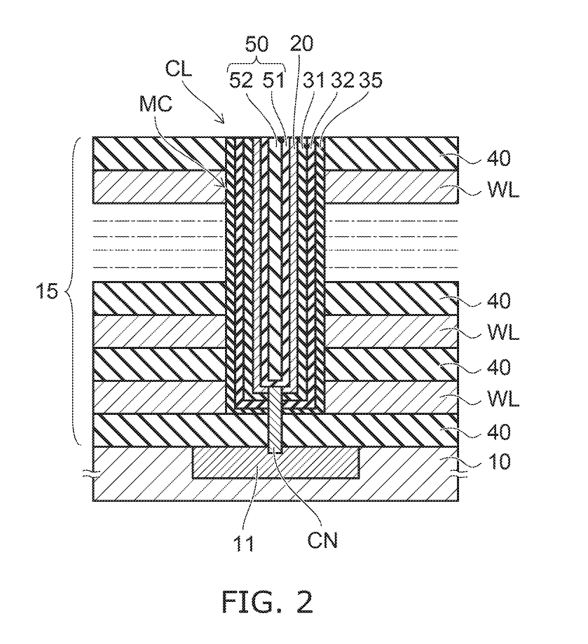

FIG. 2 is a schematic cross-sectional view of a semiconductor memory device of the embodiment. In FIG. 2, structures upper than a stacked body 15 are omitted.

In FIG. 1, two directions being parallel to a major surface of a conductive layer 10 and being perpendicular each other are taken as an X-direction and a Y-direction, and a direction perpendicular to both of the X-direction and the Y-direction is taken as a Z-direction (stacking direction).

As shown in FIG. 1, a memory cell array 1 includes a plurality of memory strings MS.

A source side selection gate SGS is provided on the conductive layer 10 (for example, substrate) via an insulating film. The insulating layer is provided on the source side selection gate SGS, and the stacked body 15 is provided on the insulating layer, the stacked body having a plurality of electrode layers WL alternately stacked with a plurality of interlayer insulating layers 40 one layer by one layer. The number of layers of the electrode layers WL shown in the drawing is one example, and the number of layers of the electrode layers WL is arbitrary.

For example, the plurality of electrode layers WL is separately stacked each other. The plurality of interlayer insulating layers 40 includes an air gap.

The insulating layer is provided on the topmost electrode layer WL, and a drain side selection gate SGD is provided on the insulating layer.

The source side selection gate SGS, the drain side selection gate SGD, and the electrode layers WL are silicon layers including silicon as a main component, and boron is, for example, doped into the silicon layers as an impurity so as to cause the silicon layers to be conductive. The source side selection gate SGS, the drain side selection gate SGD, and the electrode layers WL may include a metal silicide (for example, tungsten silicide). For example, a metal (for example, a high melting point metal such as tungsten, molybdenum, tantalum) may be used as the source side selection gate SGS, the drain side selection gate SGD, and the electrode layers WL. An insulating film mainly including, for example, silicon oxide may be provided as the interlayer insulating layer 40.

The thickness of the drain side selection gate SGD and the source side selection gate SGS can be thicker than the thickness of one electrode layer WL. The drain side selection gate SGD and the source side selection gate SGS may be provided in a plurality. The thickness of the drain side selection gate SGD and the source side selection gate SGS may be equal to or thinner than the thickness of one layer of the electrode layer WL. Here, the term “thickness” used herein refers to the thickness in the stacking direction (Z-direction) of the stacked body 15.

The stacked body 15 is provided with a pillar unit CL extending in the Z-direction. The pillar unit CL pierces the drain side selection gate SGD, the stacked body 15 and the source side selection gate SGS. The pillar unit CL is formed, for example, to be columnar or elliptically columnar. The pillar unit CL is electrically connected to the conductive layer 10.

The stacked body 15 is provided with a groove 45 piercing the drain side selection gate SGD, the stacked body 15 and the source side selection gate SGS. A source layer SL is provided in the groove 45, and a side surface of the source layer SL is covered with the insulating film. A conductive material is used as the source layer SL.

A lower end of the source layer SL is electrically connected to a channel body 20 (semiconductor body) of the pillar unit CL via the conductive layer 10. The conductive layer 10 includes, for example, a diffusion layer 11, and the diffusion layer 11 is electrically connected to the channel body 20. An upper end of the source layer SL is electrically connected to a control circuit not shown.

For example, the source layer SL may be provided between the conductive layer 10 and the stacked body 15. In such a case, a contact unit is provided in the groove 45, and the source layer SL is electrically connected to the control circuit via the contact unit.

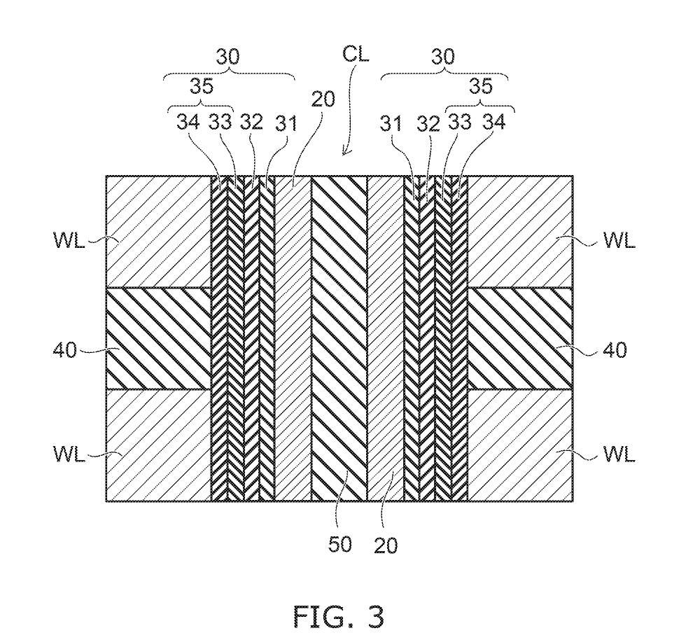

FIG. 3 is an enlarged schematic cross-sectional view of a portion of the pillar unit CL of the embodiment

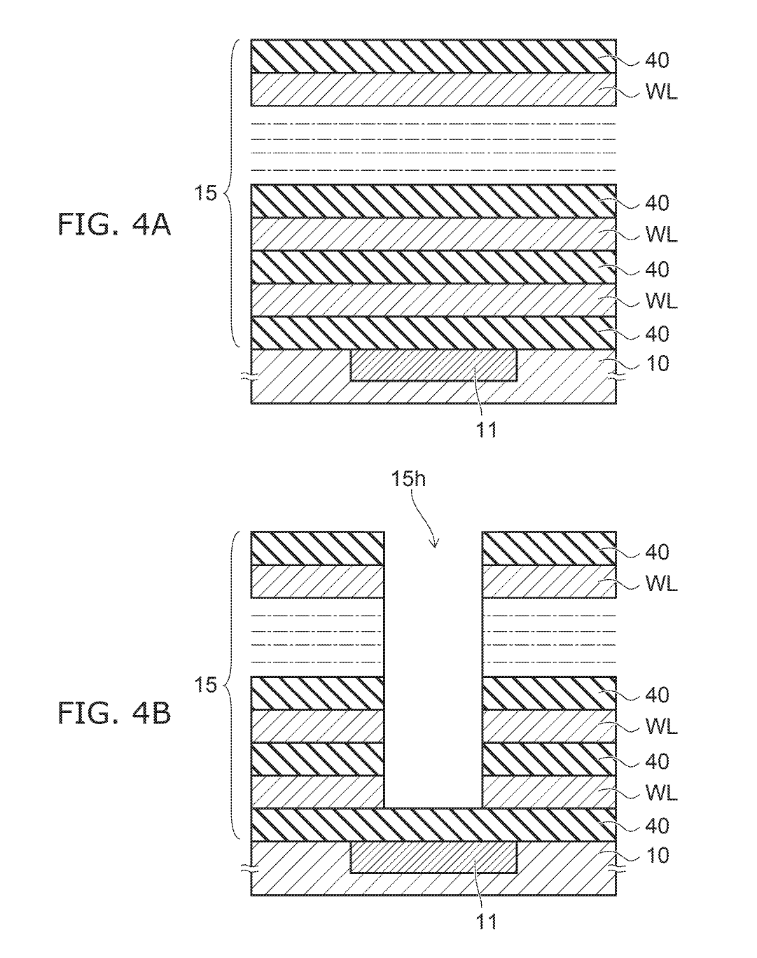

The pillar unit CL is formed in a memory hole 15h (FIG. 4B) formed in the stacked body 15 including the plurality of electrode layers WL and the plurality of interlayer insulating layers 40. The channel body 20 as a semiconductor channel is provided in the memory hole 15h. An oxide semiconductor is used as the channel body 20. The oxide semiconductor has high mobility even amid a thin film.

The channel body 20 is provided to be tubular to extend in the stacking direction of the stacked body 15. An upper end of the channel body 20 is connected to a bit line BL (interconnection) shown in FIG. 1, and a lower end side of the channel body 20 is connected to the diffusion layer 11 via the contact unit CN. The respective bit lines extend in the Y-direction.

A memory film 30 is provided between the electrode layer WL and the channel body 20. The memory film 30 includes a block insulating film 35, a charge storage film 32, and a tunnel insulating film 31.

The block insulating film 35, the charge storage film 32 and the tunnel insulating film 31 are provided in order from the electrode layer WL side between the electrode layer WL and the channel body 20. The block insulating film 35 contacts the electrode layer WL, the tunnel insulating film 31 contacts the channel body 20, and the charge storage film 32 is provided between the block insulating film 35 and the tunnel insulating film 31.

The electrode layer WL surrounds the channel body 20 via the memory film 30. A core insulating film 50 (first film 51, second film 52) is provided inside the channel body 20. At least one of the insulating film and semiconductor films having a resistance higher than a resistance of, for example, the channel body 20 is used as the first film 51.

The channel body 20 functions as a channel in a memory cell MC, and the electrode layer WL functions as a control gate of the memory cell MC. The charge storage film 32 functions as a data memory layer storing charges injected from the channel body 20. That is, the memory cell MC having a structure that the control gate surrounds the channel is formed at intersecting portions of the channel body 20 and the respective electrode layers WL.

The semiconductor memory device of the embodiment allows erasing and writing of data to be performed electrically and freely, and the data can be retained after turning off the power source.

The memory cell MC is, for example, a charge trap type. The charge storage film 32 has many trap sites trapping a charge, and is, for example, a silicon nitride film.

The tunnel insulating film 31 serves as a potential barrier when a charge is injected into the charge storage film 32 from the channel body 20 or when the charge stored in the charge storage film 32 diffuses to the channel body 20. The tunnel insulating film 31 is, for example, a silicon oxide film.

Alternatively, the tunnel insulating film 31 may include a stacked film having a structure sandwiching the charge trapping layer between one pair of silicon oxide films. When the stacked film is used as the tunnel insulating film 31, erasing operation can be performed by a low electric field in comparison with a monolayer of the silicon oxide film.

For example, the stacked film described above can be made of ONO film. In addition, the charge trapping layer can be e.g. made of a silicon nitride.

The block insulating film 35 prevents the charge stored in the charge storage film 32 from diffusing into the electrode layer WL. The block insulating film 35 includes a cap film 34 provided to contact the electrode layer WL and a block film 33 provided between the cap film 34 and the charge storage film 32.

The block film 33 is, for example, a silicon oxide film. The cap film 34 has a higher dielectric constant than the silicon oxide film, and is, for example, a silicon nitride film. By providing the cap film 34 like this to contact the electrode layer WL, a back tunnel electron injected from the electrode layer WL at erasing can be suppressed. That is, charge blocking performance can be improved by using the stacked film of the silicon oxide film with the silicon nitride film as the block insulating film 35.

As shown in FIG. 1, a drain side selection transistor STD is provided on an upper end portion of the pillar unit CL of the memory string MS, and a source side selection transistor STS is provided on a lower end portion.

The memory cell, the drain side selection transistor STD and the source side selection transistor STS are vertical type transistors which flow a current in the stacking direction (Z-direction) of the stacked body 15.

The drain side selection gate SGD functions as a gate electrode (control gate) of the drain side selection transistor STD. An insulating film which functions as a gate insulating film of the drain side selection transistor STD is provided between the drain side selection gate SGD and the channel body 20.

The source side selection gate SGS functions as a gate electrode (control gate) of the source side selection transistor STS. An insulating film which functions as a gate insulating film of the source side selection transistor STS is provided between the source side selection gate SGS and the channel body 20.

A plurality of memory cells MC including the respective electrode layers WL as the control gate are provided between the drain side selection transistor STD and the source side selection transistor STS.

The plurality of memory cells MC, the drain side selection transistor STD and the source side selection transistor STS are connected in series via the channel body 20, and form one memory string MS. These memory strings MS are arranged in the X-direction and the Y-direction and thus the plurality of memory cells are provided 3-dimensionally in the X-direction, the Y-direction and the Z-direction.

According to the embodiment, the channel body 20 includes the oxide semiconductor (oxide film). For example, at least one of zinc, aluminum, gallium and indium is used as the channel body 20.

For example, polysilicon is used as a material of the channel body 20. With downscaling of the pillar unit CL, a film thickness of the channel body 20 (polysilicon) is decreasing. At this time, the number of formed crystal grain boundaries per unit area increases. Thereby, a resistance due to grain boundary scattering increases, and decrease of operation speed of the memory may occur.

On the other hand, according to the embodiment, the oxide semiconductor is used as the channel body 20. The oxide semiconductor has high mobility even in a thin film. This makes it possible to suppress the decrease of operation speed when the thickness of the channel body 20 is decreased.

The pillar unit CL includes the contact unit CN electrically connecting the channel body 20 to outside of the pillar unit CL. The contact unit CN pierces a bottom of the pillar unit CL and the interlayer insulating layer 40 to reach the diffusion layer 11.

The channel body 20 is electrically connected to the diffusion layer 11 via the contact unit CN. The contact unit CN includes a material different from the channel body 20, and includes, for example, a metal. For example, at least one of tantalum, titanium, aluminum, cobalt, nickel, magnesium, tungsten, molybdenum, chromium, zirconium, silicon and boron is used as the contact unit CN. For example, a metal compound and an oxynitride of the above materials may be used as the contact unit CN, and materials with a small diffusion coefficient to Silicon are used.

For example, as viewed in the stacking direction, when each of the cross-sections (the plane perpendicular to the stacking direction) of the channel body 20 and the contact unit CN are elliptically-shaped, the maximum width of the cross-section of the channel body 20 is larger than the maximum width of the cross-section of the contact unit CN. Here, the term “the maximum width” used herein refers to the major diameter. That is, the term “the maximum width” used herein refers to the longest span in the direction perpendicular to the stacking direction.

Furthermore, when the channel body 20 and contact unit CN are columnar, the diameter of the channel body 20 is larger than the diameter of the contact unit CN. That is, as viewed in the stacking direction, the longest span of the cross-section of the channel body 20 is larger than the longest span of the cross-section of the contact unit CN regarding each of the cross-sections (the plane perpendicular to the stacking direction) of the channel body 20 and the contact unit CN.

The first film 51 is provided inside the channel body 20. The first film 51 includes an oxide of materials used for the contact unit CN. For example, when tantalum is used as the contact unit CN, the first film 51 includes a tantalum oxide.

The diffusion layer 11 is electrically connected to a peripheral circuit. The diffusion layer 11 contacts a lower end portion of the contact unit CN and is electrically connected to the channel body 20 via the contact unit CN.

For example, the oxide semiconductor of the same material as the channel body 20 is used as the contact unit CN. In such a case, in order to form a film having good step coverage (coverage) in a contact hole 10h, for example, an ALD method (atomic layer deposition) or a CVD method (chemical vapor deposition) or the like are carried out under an oxidizing atmosphere. This oxidizes the conductive layer 10 exposed to a bottom of the contact hole. Therefore, a contact resistance between the conductive layer 10 and the contact unit CN having the oxide semiconductor formed increases.

On the other hand, according to the embodiment, a material (metal) different from the material (oxide semiconductor) of the channel body 20 is used as the contact unit CN. A metal film is, for example, formed under a nitrogen atmosphere. This suppresses oxidation of the conductive layer 10, and makes it possible to reduce the contact resistance between the contact unit CN and the conductive layer 10.

For example, the first film 51 provided on the contact unit CN and inside the channel body 20 includes the same metal as the contact unit CN. In such a case, the resistance of the first film 51 is lower than the resistance of the channel body 20. Thereby, the memory cell is always in ON state (low resistance state). Therefore, function of the memory cell is lost.

On the other hand, according to the embodiment, the first film 51 on the contact unit CN and inside the channel body 20 includes an oxide film of the same metal as the contact unit CN. In such a case, the resistance of the first film 51 is higher than the resistance of the channel body 20. Thereby, ON-OFF control of the memory cell can be performed by using change of the resistance of the channel body 20.

Furthermore, an electric character of the oxide semiconductor depends heavily on the content of oxygen in the oxide semiconductor. Therefore, as viewed in the stacking direction, when the longest span of the cross-section of the contact unit CN is smaller than the longest span of the cross-section of the channel body 20 regarding each of the cross-sections (the plane perpendicular to the stacking direction) of the contact unit CN and the channel body 20, it is possible to decrease the contact area of the oxide semiconductor of the channel body 20 and the contact unit CN.

As a result, it can be achieved to suppress the oxygen diffusion from oxide semiconductor of the channel body 20 to the contact unit CN, and the deterioration of the electric character of the oxide semiconductor of the channel body 20.

According to the embodiment, it can be achieved to suppress the increase of the resistance associated with high integration of the memory cell.

Next, with reference to FIG. 4A to FIG. 6B, a method for manufacturing the semiconductor device of the embodiment will be described.

As shown in FIG. 4A, the diffusion layer 11 is formed in the conductive layer 10. The stacked body 15 is formed on the conductive layer 10 via the interlayer insulating layer 40, and the stacked body includes the plurality of electrode layers WL alternately stacked with the plurality of inter layer insulating layers 40. Between the conductive layer 10 and the stacked body 15, for example, the source side selection gate SGS may be formed and the source layer SL may be formed.

For example, amorphous silicon with a thickness of 30 nm is used as the electrode layer WL. For example, a silicon oxide film with a thickness of 30 nm is used as the interlayer insulating layer 40.

The electrode layer WL and the interlayer insulating layer 40 are formed, for example, by the CVD method. After that, the stacked body 15 is subjected to a heat treatment (for example, 950° C., 30 seconds), and the amorphous silicon used for the electrode layer WL is crystallized.

As shown in FIG. 4B, the hole 15h (first hole) piercing the stacked body 15 and reaching the lowest interlayer insulating layer 40 is formed. The hole 15h is formed with a width of a diameter of 80 nm, for example, by an RIE method (Reactive Ion Etching) using a mask not shown.

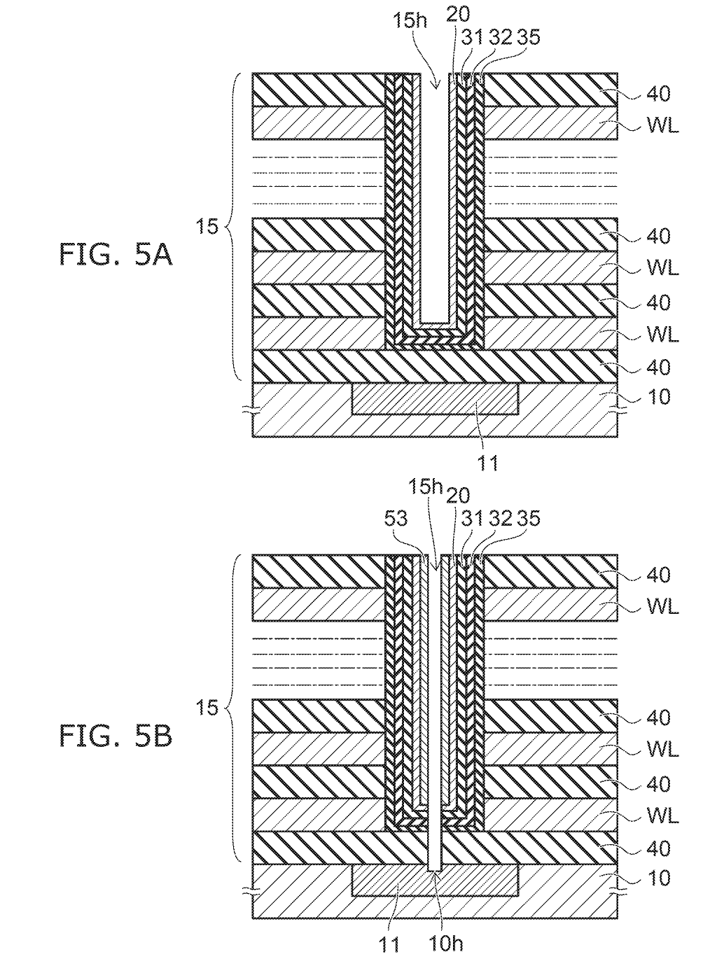

After that, as shown in FIG. 5A, respective films (memory film 30, channel body 20 or the like) shown in FIG. 3 are formed on an inner wall (sidewall and bottom) of the hole 15h. The respective films are, for example, formed by the ALD method.

For example, an aluminum oxide film with a thickness of 15 nm is used as the block insulating film 35. Source gases for forming the aluminum oxide film include TMA (trimethylaluminium) and O₃.

For example, a silicon nitride film with a thickness of 5 nm is used as the charge storage film 32. Source gases for forming the silicon nitride film include 3DMAS (trisdimethyl amino silane) and NH₃.

For example, a silicon oxide film with a thickness of 8 nm is used as the tunnel insulating film 31. Source gases for the silicon oxide film include 3DMAS and O₃.

The oxide semiconductor is used as the channel body 20. For example, a zinc oxide film with a thickness of 5 nm is used as the channel body 20. The ALD method using DEZ (diethylzinc) and O₃ as source gases is used for forming the zinc oxide film. When forming the zinc oxide film, the film is formed, for example, at a temperature of 300° C., for DEZ supply time of 1 second, and for O₃ supply time of 3 seconds.

After that, a mask film 53 is formed as a mask inside the channel body 20. For example, at least one of the silicon oxide film and the silicon nitride film with a thickness of 5 nm is used as the mask 53.

As shown in FIG. 5B, the contact hole 10h (second hole) is formed on a bottom of the hole 15h. The contact hole 10h pierces the respective films formed at the bottom of the hole 15h and the interlayer insulating films 40, and reaches the conductive layer 10. Thereby, the channel body 20 is exposed to a side wall of the contact hole 10h. The diffusion layer 11 is exposed to a bottom of the contact hole 10h.

After that, the mask 53 formed inside the channel body 20 is removed by using, for example, the RIE method. Thereby, a side surface of the channel body 20 is exposed to the hole 15h.

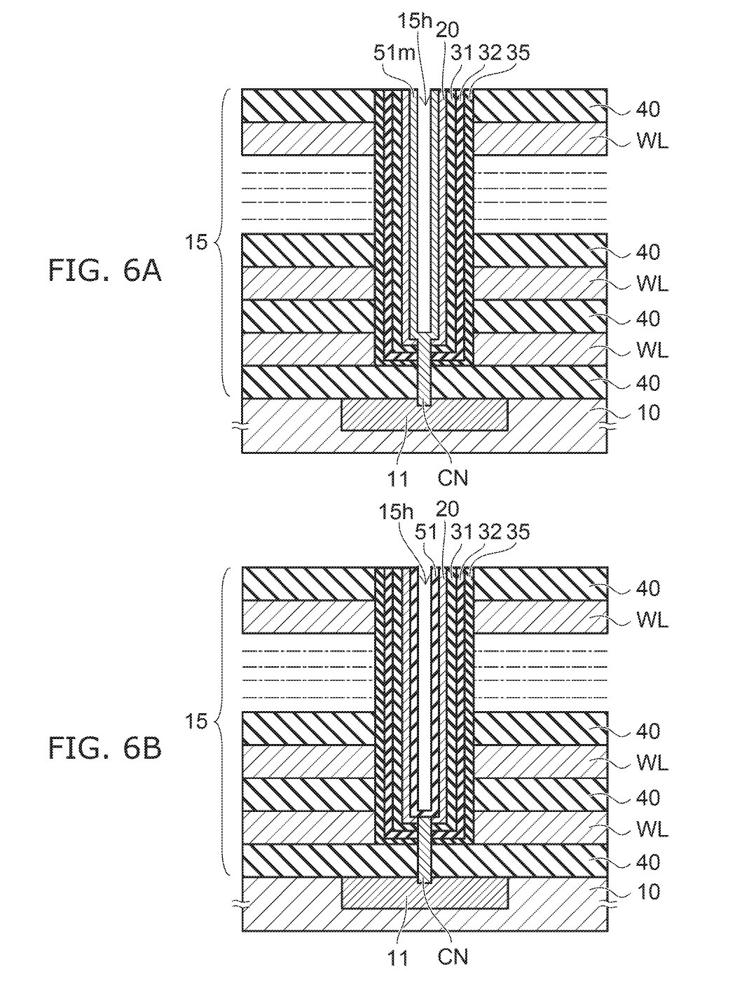

As shown in FIG. 6A, a metal film 51m (conductive film) is formed on an inner wall of the contact hole 10h and inside the channel body 20. The metal film 51m is formed, for example, by using the ALD method. For example, a tantalum film with a thickness of 3 nm is used as the metal film 51m.

This forms the contact unit CN. The contact unit CN is electrically connected to the channel body 20 and the diffusion layer 11.

As shown in FIG. 6B, the first film 51 oxidized from the metal film 51 is formed inside the channel body 20. The first film 51 is formed by a heating treatment of the metal film 51. The heating treatment is performed, for example, at an atmospheric pressure of oxygen atmosphere, for 3 minutes at 80° C. For example, when the tantalum film is used as the metal film 51m, oxidation is processed to a depth of 3 nm from a surface, and the tantalum oxide film is formed.

On the other hand, the metal film 51m buried in the contact hole 10h is not oxidized because it is formed in the contact hole 10h. That is, only the metal film 51m formed inside the channel body 20 is oxidized.

Next, as shown in FIG. 2, the second film 52 (for example, silicon oxide film) is formed inside the first film 51. A resistance of the second film 52 is higher than the resistance of the channel body 20. Thereby, the pillar unit CL is formed.

After that, the grove 45 piercing the stacked body 15 is formed in order to form device isolation and contact to the electrode layer WL. The insulating film and the source layer SL are formed in the formed groove 45. After that, bit lines or the like are formed, and the semiconductor memory device of the embodiment is formed.

According to the embodiment, it becomes possible to suppress the increase of the resistance associated with high integration of memory cells.

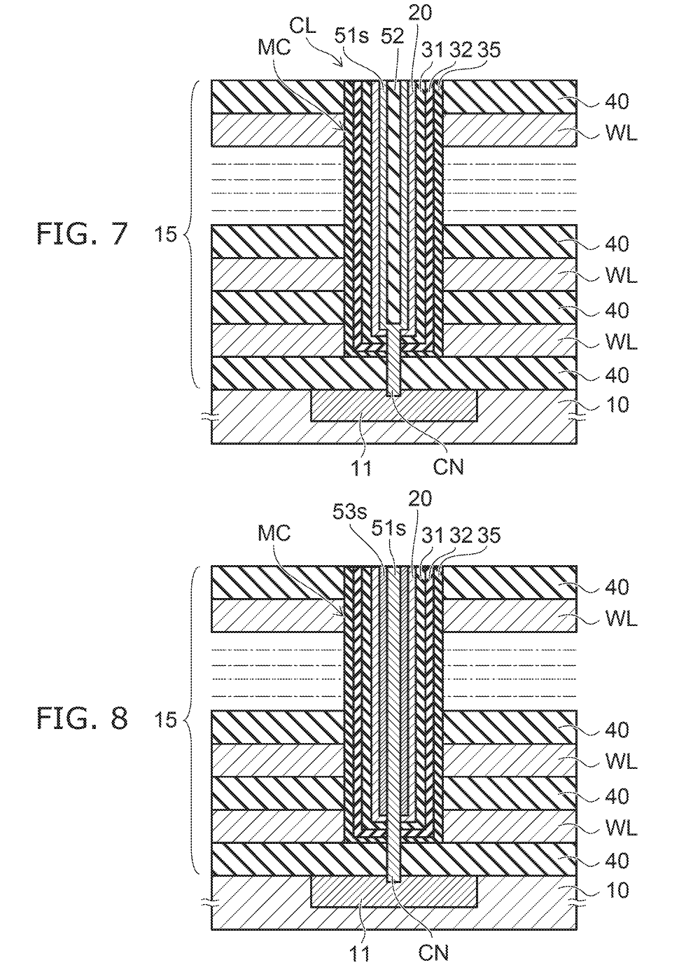

FIG. 7 and FIG. 8 are schematic cross-sectional views of a memory string of another embodiment. In FIG. 7 and FIG. 8, structures above and below the stacked body are omitted.

According to the embodiment, amorphous silicon is used as the contact unit CN. This makes it possible to omit the heating treatment in forming the first film 51 using the metal film 51m in comparison with using the metal recited above for the contact unit CN.

As shown in FIG. 7, the contact unit CN is collectively formed with a first film 51s (conductive film). The contact unit CN and the first film 51s include amorphous silicon.

The second film 52 is provided inside the first film 51s. The second film 52 includes, for example, a silicon oxide film. A resistance of the second film 52 is higher than the resistance of the channel body 20.

For example, as shown in FIG. 8, a mask film 53s may be provided between the first film 51s and the channel body 20. In such a case, the mask film 53s includes amorphous silicon similar to the contact unit CN and the first film 51s.

Also in the embodiment, the channel body 20 includes the oxide semiconductor. Mobility of the channel body 20 is higher than mobility of each of the first film 51s and the mask film 53s. This makes it possible to suppress the decrease of the operation speed when the thickness of the channel body 20 is thinned. It becomes possible to reduce the contact resistance between the contact unit CN and the conductive layer 10.

Next, a method for manufacturing a semiconductor device of another embodiment will be described.

Similar to the manufacturing method of FIG. 4A to FIG. 5B of the embodiment recited above, the diffusion layer 11 is formed in the conductive layer 10. The stacked body 15 including the plurality of electrode layers WL alternately stacked with the plurality of interlayer insulating layers 40 is formed on the conductive layer 10 via the interlayer insulating layer 40.

Next, the hole 15h piercing the stacked body 15 and reaching the lowest interlayer insulating layer 40 is formed, and the respective films shown in FIG. 3 are formed on the inner wall of the hole 15h. The oxide semiconductor is used as the channel body 20.

After that, the mask film 53 is formed as a mask inside the channel body 20. The contact hole 10h is formed on the bottom of the hole 15h. The contact hole 10h pierces the respective films formed on the bottom of the hole 15h and the interlayer insulating layer 40, and reaches the conductive layer 10.

Thereby, the channel body 20 is exposed to the side wall of the contact hole 10h. The diffusion layer 11 is exposed to the bottom of the contact hole 10h.

After that, the mask film 53 formed inside the channel body 20 is removed by using, for example, the RIE method. This exposes the side surface of the channel body 20 to the hole 15h. When amorphous silicon is used as the mask film 53, the mask film 53 does not need to be removed.

Next, the first film 51s based on amorphous silicon is formed on the inner wall of the contact hole 10h and inside the channel body 20. A thickness of amorphous silicon is, for example, 3 nm.

Thereby, the contact unit CN is formed. The channel body 20 is electrically connected to the diffusion layer 11 via the contact unit CN.

After that, the second film 52 is formed inside the first film 51s. When the mask film 53s is not removed, the second film 52 needs not to be formed. At this time, the first film 51s is formed inside the mask film 53s.

Amorphous silicon is crystallized by the heating treatment. The heating treatment is performed, for example, at 950° C. for 30 seconds.

Thereby, the pillar unit CL shown in FIG. 7 and FIG. 8 is formed. After that, the grove 45 piercing the stacked body 15 is formed in order to form device isolation and contact to the electrode layer WL. The insulating film and the source layer SL are formed in the formed groove 45. After that, the bit lines BL or the like are formed and the semiconductor memory device of the embodiment is formed.

According to the embodiment, it can be achieved to suppress the increase of the resistance associated with high integration of the memory cell. Different from the case using the metal film 51m, it becomes possible to omit the heating treatment when forming the first film 51.

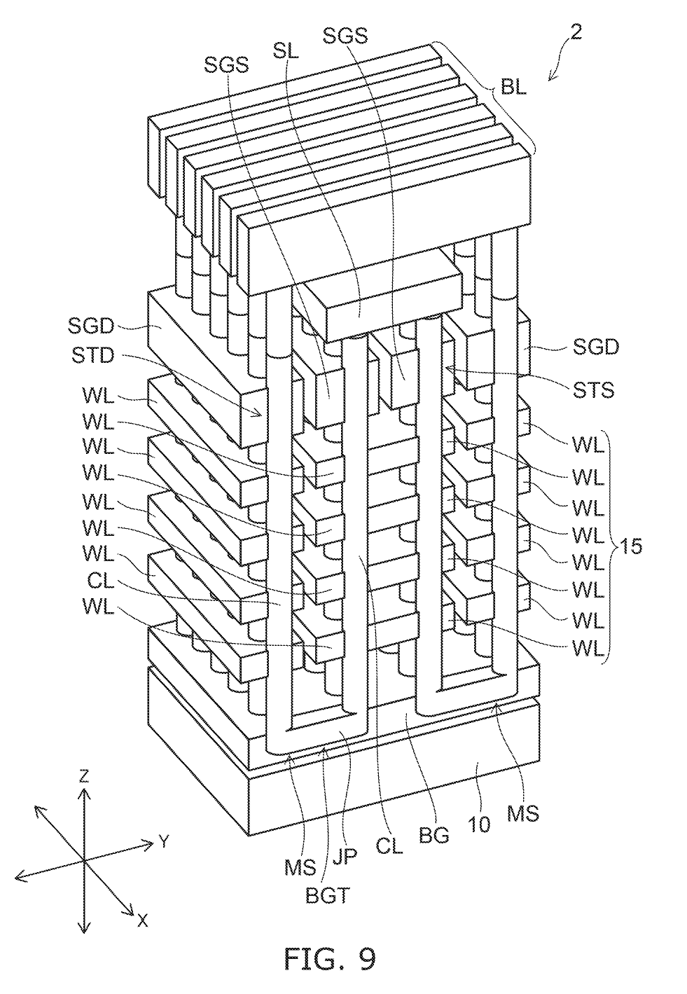

FIG. 9 is a schematic perspective view of the memory cell array of another example of the semiconductor memory device of the embodiment.

Also in FIG. 9 similar to FIG. 1, the insulating layer or the like is omitted for convenience of viewing the drawing.

A back gate BG is provided on the conductive layer 10 via the insulating layer. The stacked body 15 including the plurality of electrode layers WL alternately stacked with the plurality of interlayer insulating layers 40 is formed on the back gate BG.

One memory string MS is formed to be U-shaped, having one pair of pillar units CL extending in the Z-direction and a coupling unit JP coupling a lower end of each of the one pair of pillar units CL. The pillar unit CL is formed, for example, to be columnar or elliptically columnar, pierces the stacked body 15, and reaches the back gate BG.

The drain side selection gate SGD is provided on an upper end portion of one of the one pair of pillar units CL in the U-shaped memory string MS, and the source side selection gate SGS is provided on an upper end portion of the other. The drain side selection gate SGD and the source side selection gate SGS are provided on the topmost electrode layer WL via the interlayer insulating layer. The stacked body 15 includes the source side selection gate SGD, the drain side selection gate SGD, and the plurality of electrode layers WL.

The drain side selection gate SGD and the source side selection gate SGS are isolated by a slit in the Y-direction. The stacked body 15 including the drain side selection gate SGD and the stacked body 15 including the source side selection gate SGS are isolated by the slit in the Y-direction. That is, the stacked body 15 between the one pair of pillar units CL of the memory string MS is isolated by the slit in the Y-direction.

The source layer SL is provided on the source side selection gate SGS via the insulating layer. The plurality of bit lines BL are provided on the drain side selection gate SGD and the source layer SL via the insulating layer. The respective bit lines BL extend in the Y-direction.

Also when using a memory cell array 2, similar to the embodiment described above, the channel body 20 includes the oxide semiconductor. This makes it possible to suppress the decrease of the operation speed when the thickness of the channel body 20 is thinned. It becomes possible to decrease the contact resistance between the contact unit CN and the conductive layer 10.

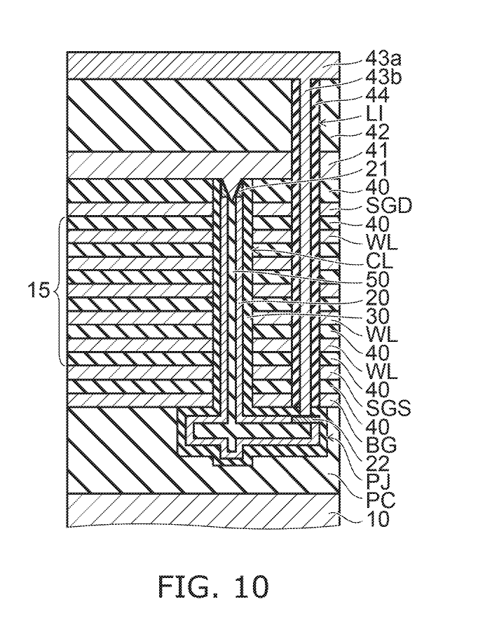

FIG. 10 is a schematic cross-sectional view of a memory string of still another embodiment.

As shown in FIG. 10, an insulating layer PC is provided on the conductive layer 10. For example, a silicon oxide film is used as the insulating layer PC.

The back gate BG is provided on the insulating layer PC. For example, tungsten is used as the back gate BG.

The source side selection gate SGS is provided on the back gate BG via the interlayer insulating layer 40. The stacked body 15 including the plurality of electrode layers WL alternately stacked with the plurality of interlayer insulating layers 40 is formed on the source side selection gate SGS via the interlayer insulating layer 40. The drain side selection gate SGD is provided on the stacked body 15 via the interlayer insulating layer 40.

Each of the source side selection gate SGS, the drain side selection gate SGD, the electrode layer WL, and the interlayer insulating layer 40 includes the same material as the embodiment described above.

A first conductive layer 41 is provided on the drain side selection gate SGD via the interlayer insulating layer 40. A second conductive layer 43a is provided on the first conductive layer 41 via an insulating layer 42. Each of the first conductive layer 41 and the second conductive layer 43a includes, for example, tungsten.

The stacked body 15 is provided with the pillar unit CL piercing from the interlayer insulating layer 40 on the drain side selection gate SGD to the back gate BG and reaching the insulating layer PC. The pillar unit CL includes the memory film 30, the channel body 20, and the core insulating film 50 as well as the embodiment described above. An upper portion of the pillar unit CL contacts the first conductive layer 41.

The channel body 20 includes a first diffusion layer 21 (first semiconductor layer). The first diffusion layer 21 is provided on the upper end of the channel body 20. The first diffusion layer 21 is, for example, an n-type semiconductor. For example, a nitride semiconductor is used as the first diffusion layer 21, and an oxynitride semiconductor may be used. The channel body 20 is electrically connected to the first conductive layer 41 via the first diffusion layer 21.

As described layer, the first diffusion layer 21 is formed, for example, by performing a nitride treatment of the channel body 20.

The stacked body 15 is provided with an interconnection unit LI piercing from the insulating layer 42 to the back gate BG and reaching the insulating layer PC. An insulating film 44 is provided on a side wall of the interconnection unit LI, and a conductive film 43b is provided inside the insulating film 44. The conductive film 43b is formed collectively with the second conductive layer 43a.

A connection unit PJ is provided in the insulating layer PC. The pillar unit CL is electrically connected to the interconnection unit LI via the connection unit PJ.

For example, the memory film 30 is provided on a wall surface of the connection unit PJ. The channel body 20 is provided inside the memory film 30. The core insulating film 50 is provided inside the channel body 20. The memory film 30, the channel body 20, and the core insulating film 50 provided in the connection unit PJ are collectively provided from the pillar unit CL to the connection unit PJ.

The channel body 20 of the connection unit PJ includes a second diffusion layer 22 (second semiconductor). The second diffusion layer 22 is provided between the channel body 20 and the interconnection unit LI. The channel body 20 is electrically connected to the interconnection unit LI via the second diffusion layer 22.

The second diffusion layer 22 is, for example, an n-type semiconductor. For example, the nitride semiconductor is used as the second diffusion layer 22, and the oxynitride semiconductor may be used. As described layer, the second diffusion layer 22 is formed, for example, by performing the nitride treatment of the channel body 20.

According to the embodiment, as well as the embodiment described above, the channel body 20 includes the oxide semiconductor. For example, the oxide semiconductor including at least one of zinc, aluminum, gallium, and indium is used as the channel body 20.

Thereby, as well as the embodiment described above, it becomes possible to suppress the decrease of the operation speed when the thickness of the channel body is thinned.

Furthermore, the first diffusion layer 21 is provided on an upper portion of the channel body 20. The nitride semiconductor is used as the first diffusion layer 21, and for example, at least one of zinc nitride, aluminum nitride, gallium nitride, and indium nitride is used.

For example, in a charge injection type memory, an electron written in a floating gate is extracted by increasing a substrate potential. As other erasing method, GIDL (Gate Induced Drain Leakage) erasing can be also used, in GIDL erasing, a channel potential of the memory cell is boosted by using GIDL current generated in the channel at an upper end of the drain side selection gate SGD.

In this case, positive holes generated by applying a high electric field to the semiconductor film (first diffusion layer 21) with a high impurity concentration formed near an upper end portion of the drain side selection gate SGD are supplied to the channel body 20, and the channel potential is increased. The potential of the electrode layer WL is set to, for example, the ground potential (0V), and thereby the electron of the charge storage film 32 is extracted by the potential difference between the channel body 20 and the electrode layer WL, or the positive hole is injected into the charge storage film 32, and data erasing operation is performed.

At this time, for example, the amount of positive holes generated from the semiconductor film depends on a band gap of the semiconductor film. For example, the amount of positive holes generated from the semiconductor film decreases with increasing band gap of the semiconductor film.

According to the embodiment, a nitride semiconductor doped with an n-type impurity is used as the first diffusion layer 21. The band gap of the nitride semiconductor is narrower than the band gap of the oxide semiconductor. Therefore, GIDL is likely to occur in the nitride semiconductor more than the oxide semiconductor. That is, it becomes possible to improve performance of the data erasing operation by using the nitride semiconductor as the first diffusion layer 21.

In addition to the above, the nitride semiconductor doped with the n-type impurity is used as the second diffusion layer 22 as well as the first diffusion layer 21. This makes it possible to improve the performance of the data erasing operation as well as the first diffusion layer 21 described above.

According to the embodiment, it becomes possible to suppress the increase of the resistance associated with high integration of the memory cell.

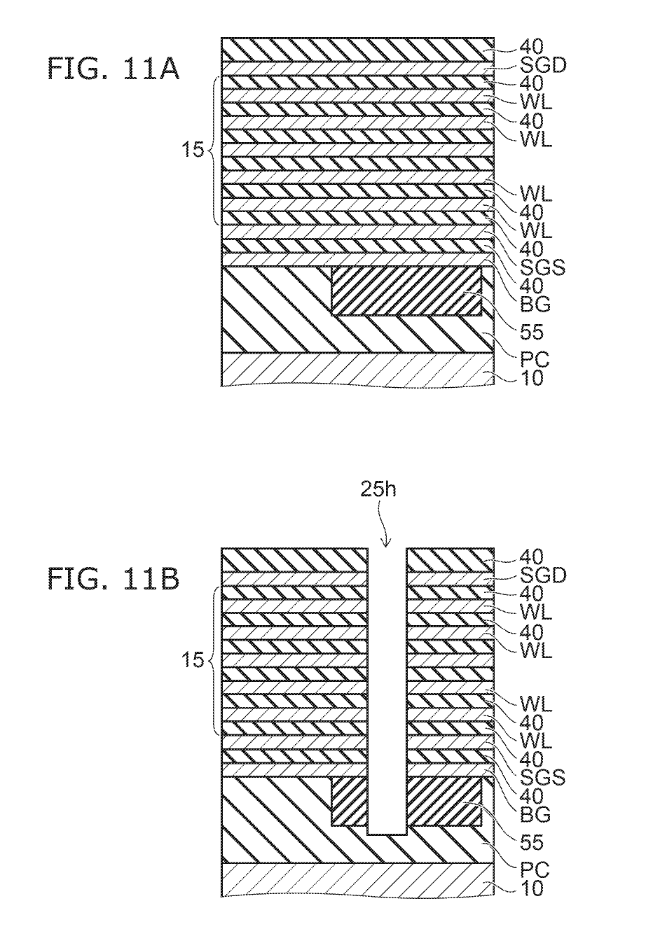

Next, with reference to FIG. 11A to FIG. 18B, a method for manufacturing a semiconductor memory device of a still another embodiment will be described.

As shown in FIG. 11A, the insulating layer PC is formed on the conductive layer 10. For example, the silicon oxide film is used as the insulating layer PC. A concave portion is formed in an upper portion of the insulating layer PC, and a sacrifice layer 55 is formed in the concave portion.

In a process described later, the sacrifice layer 55 is removed, and the connection unit PJ is formed in the removed portion (replace process). A selectively removable material is used as the sacrifice layer 55, and for example, at least one of amorphous silicon and the silicon nitride film is used.

The back gate BG is formed on the insulating layer PC and the sacrifice layer 55. A conductive material is used as the back gate BG, and for example, tungsten is used.

The source side selection gate SGS is formed on the back gate BG via the interlayer insulating film 40. The stacked body 15 having the plurality of electrode layers WL alternately stacked with the plurality of interlayer insulating layers 40 is formed on the source side selection gate SGS via the interlayer insulating layer 40.

The drain side selection gate SGD is formed on the stacked body 15 via the interlayer insulating layer 40. The interlayer insulating layer 40 is formed on the drain side selection gate SGD.

For example, amorphous silicon is used as the source side selection gate SGS, the drain side selection gate SGD, and the electrode layer WL. For example, the oxide silicon film is used as the interlayer insulating layer 40.

In a process described later, for example, the material (for example, amorphous silicon) used as the source side selection gate SGS, the drain side selection gate SGD, and the electrode layer WL is removed, and a material such as a metal or the like may be formed in the removed portion (replace process of electrode layer and each selection gate).

As shown in FIG. 11B, a hole 25h piercing the sacrifice layer 55 from the interlayer insulating layer 40 on the selection side gate SGD and reaching the insulating layer PC is formed. The hole 25 is formed, for example, by the RIE method using a mask not shown. The insulating layer PC is exposed to a bottom surface of the hole 25h. The hole 25 needs not to reach, for example, the insulating layer PC and may reach the sacrifice layer 55.

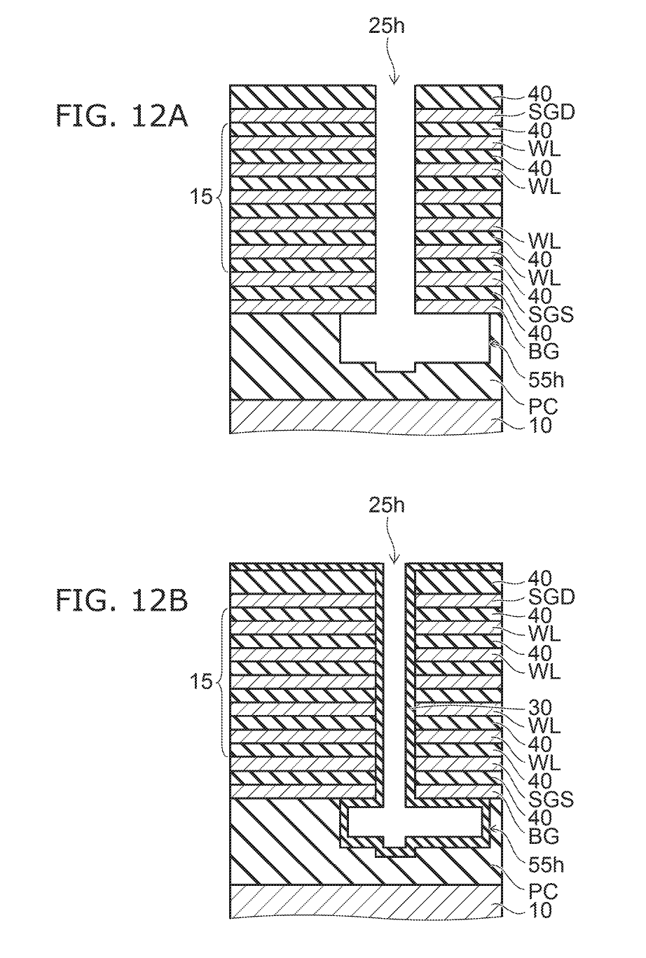

As shown in FIG. 12A, the sacrifice layer 55 is removed by wet etching through the hole 25h. Thereby, a cavity 55h is formed in a portion where the sacrifice layer 55 is removed. The cavity 55h is collectively formed with the hole 25h.

As shown in FIG. 12B, the memory film 30 shown in FIG. 3 is formed on an inner wall of the hole 25h and an inner wall of the cavity 55h. The respective films are formed by, for example, the ALD method, and may be formed by a LPCVD method (low pressure chemical vapor deposition).

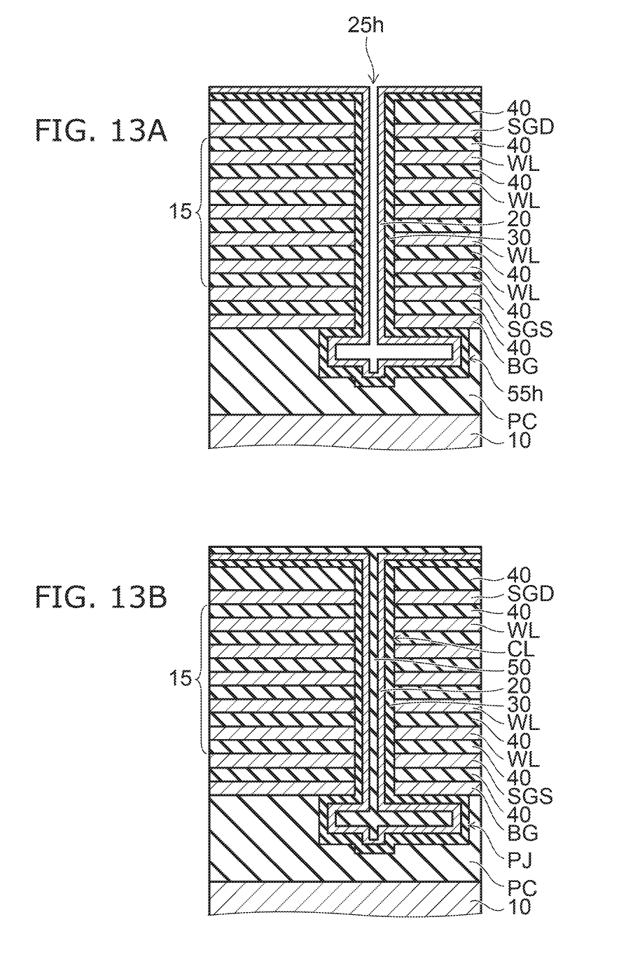

As shown in FIG. 13A, the channel body 20 is formed inside the memory film 30. For example, the oxide semiconductor is used as the channel body 20. For example, at least one of the nitride semiconductor and the oxynitride semiconductor may be used as the channel body 20.

For example, when the oxide semiconductor (for example, ZnO) is used as the channel body 20, the nitride semiconductor (for example, ZnN) may be formed by the nitride treatment of the channel body 20. For example, a heating treatment method or plasma treatment method in a nitrogen atmosphere is used as the nitride treatment.

For example, when the nitride semiconductor (for example, ZnN) is used as the channel body 20, the oxynitride semiconductor (for example, ZnON) may be formed by the oxidation treatment of the channel body 20.

As shown in FIG. 13B, the core insulating film 50 is formed inside the channel body 20. The core insulating film 50 is formed by, for example, the ALD method. For example, the silicon oxide film is used as the core insulating film 50. Thereby, the pillar unit CL is formed in the hole 15h, and the connection unit PJ is formed in the cavity 55h.

After that, each of the memory film 30, the channel body 20, and the core insulating film 50 formed on the interlayer insulating layer 40 is removed.

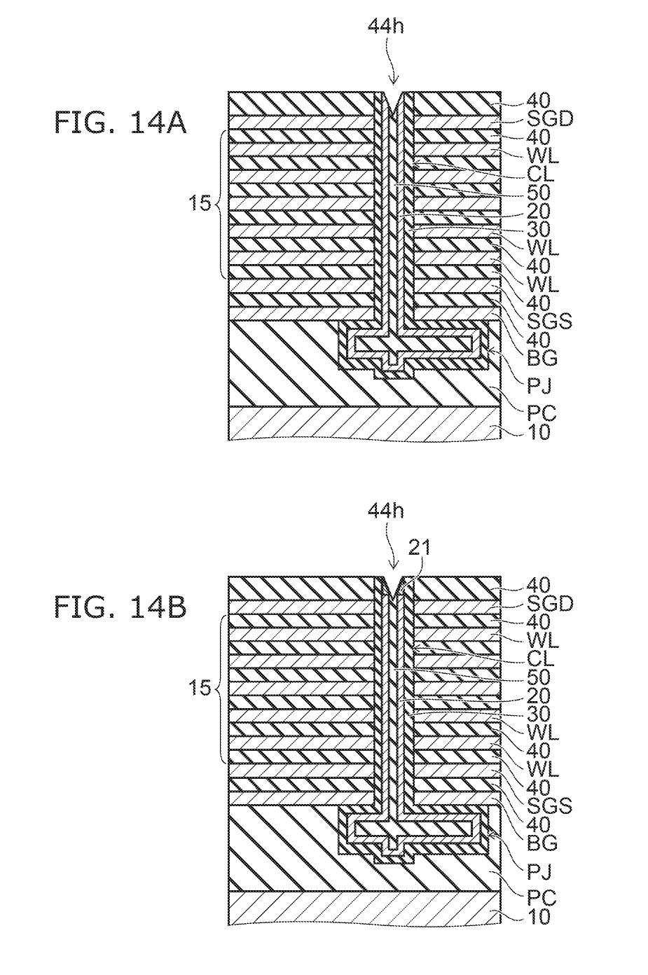

As shown in FIG. 14A, the upper portion of the pillar unit CL is etched back by, for example, the RIE method using a mask not shown. Thereby, a cavity 44h is formed. The channel body 20 is exposed to the cavity 44h.

As shown in FIG. 14B, the nitride treatment of the upper portion of the channel body 20 is performed. Thereby, the first diffusion layer 21 is formed. For example, the heating treatment method or plasma treatment method in the nitrogen atmosphere is used as a method of the nitride treatment.

For example, when the oxide semiconductor (for example, ZnO) is formed as the channel body 20, at least one of the nitride semiconductor (ZnN) and the oxynitride semiconductor (ZnON) is formed as the first diffusion layer 21.

For example, when the oxynitride semiconductor (for example, ZnON) is formed as the channel body 20, at least one of the nitride semiconductor (ZnN) and the oxynitride semiconductor (ZnON) having a nitrogen concentration higher than a nitrogen concentration of the channel body 20 is formed as the first diffusion layer 21.

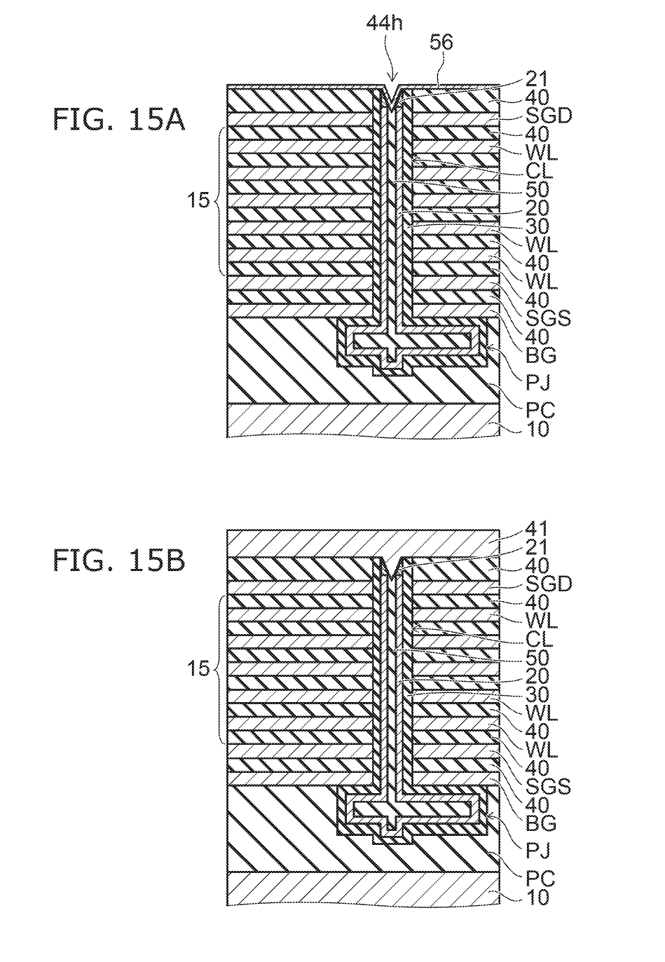

As shown in FIG. 15A, a metal film 56 is formed on the cavity 44h and the interlayer insulating layer 40. For example, at least one of aluminum and titanium is used as the metal film 56.

After that, an impurity is doped into the first diffusion layer 21 by performing the heating treatment. Thereby, the first diffusion layer 21 becomes the n-type semiconductor. After the impurity is doped into the first diffusion layer 21, the metal film 56 is removed.

As shown in FIG. 15B, the first conductive layer 41 is formed in the cavity 44h and on the interlayer insulating layer 40. The first conductive layer 41 is electrically connected to the channel body 20 via the first diffusion layer 21. For example, tungsten is used as the first conductive layer 41, and polysilicon may be used.

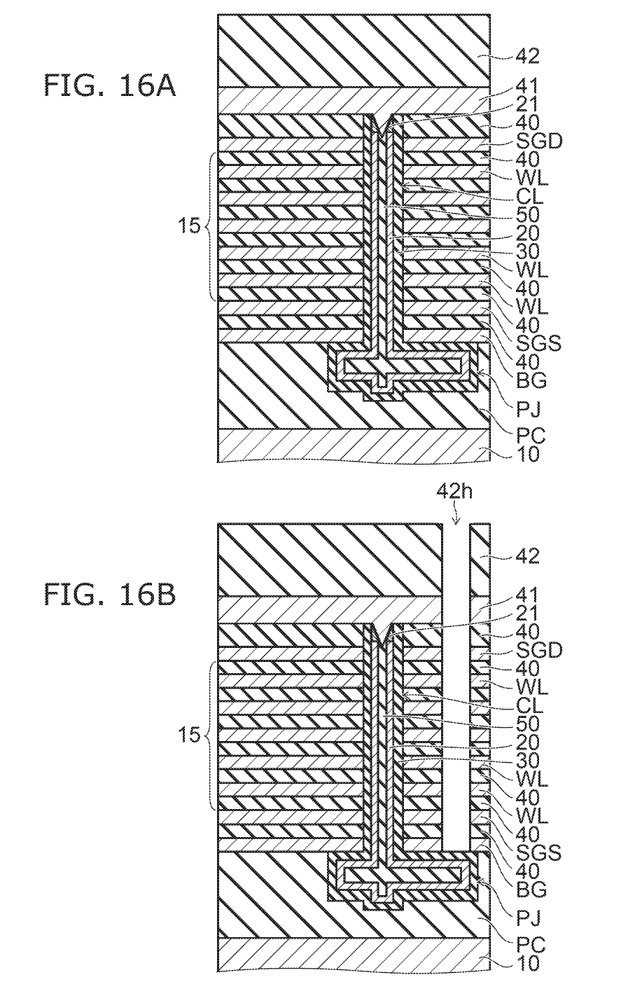

As shown in FIG. 16A, the insulating layer 42 is formed on the first conductive layer 41. For example, the silicon oxide film is used as the insulating layer 42. For example, a PECVD method (plasma-enhanced chemical vapor deposition) is used as a forming method of the insulating layer 42.

As shown in FIG. 16B, a hole 42h piercing from the insulating layer 42 to the back gate BG is formed. The hole 42h is formed by, for example, the RIE method using a mask not shown. The memory film 30 of the connection unit PJ is exposed to a lower surface of the hole 42h.

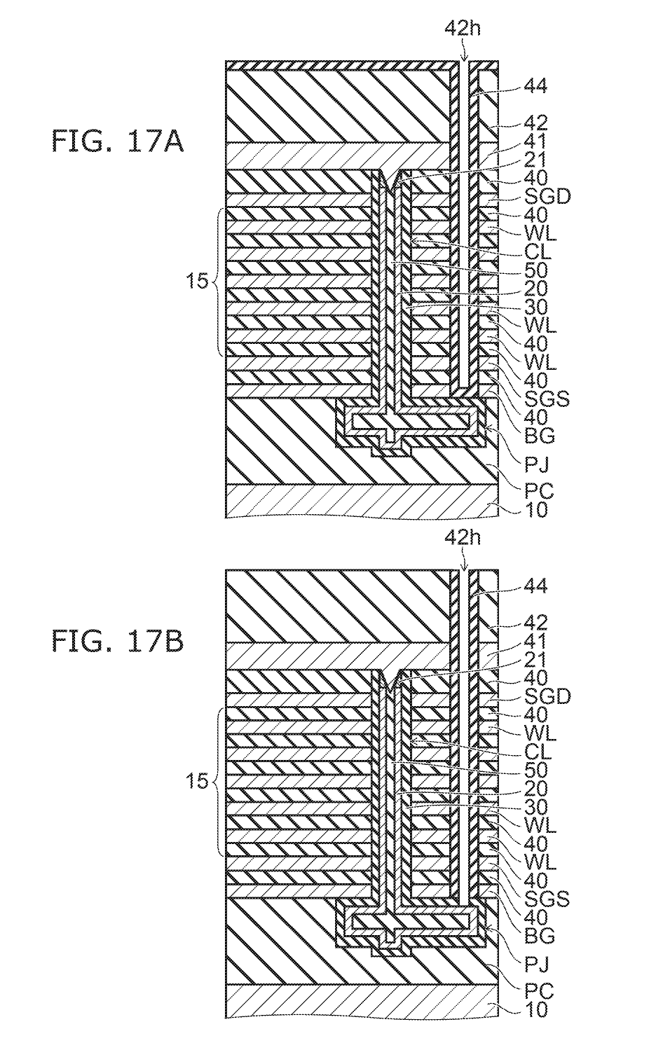

As shown in FIG. 17A, the insulating film 44 is formed on an inner wall of the hole 42h. For example, the silicon oxide film is used as the insulating film 44. For example, the ALD method is used as a forming method of the insulating film 44.

As shown in FIG. 17B, the hole 42h is thrust back to pierce the insulating film 44 formed on a bottom of the hole 42h and the memory film 30 of the connection unit PJ, and to reach the channel body 20. For example, the RIE method using a mask not shown is used as a method for thrusting back the hole 42h. The channel body 20 of the connection unit PJ is exposed to the bottom of the hole 42h which is thrust back.

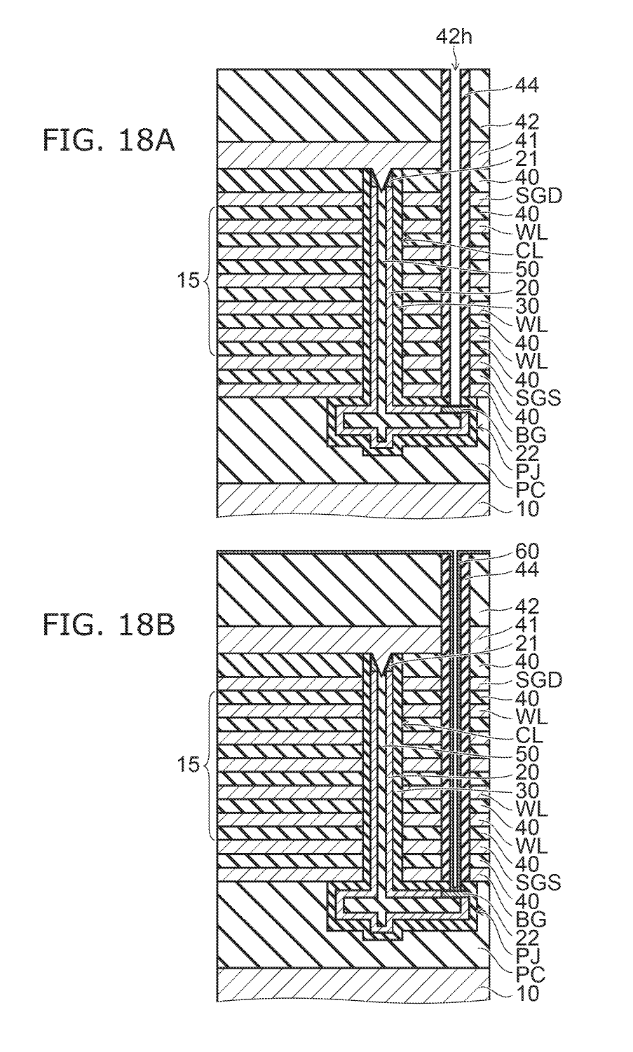

As shown in FIG. 18A, the nitride treatment of an exposed portion of the channel body 20 exposed to the hole 42h is performed. Thereby, the second diffusion layer 22 is formed. For example, the heating treatment method or the plasma treatment method in the nitrogen atmosphere is used as the nitride treatment.

For example, when the oxide semiconductor is formed as the channel body 20, at least one of the nitride semiconductor and the oxynitride semiconductor is formed as the second diffusion layer 22.

For example, when the oxynitride semiconductor is formed as the channel body 20, at least one of the nitride semiconductor and the oxynitride semiconductor having a nitrogen concentration higher than a nitrogen concentration of the channel body 20 is formed.

As shown in FIG. 18B, a metal film 60 is formed inside the insulating film 44, on a bottom surface of the hole 42h and the insulating layer 42. For example, at least one of aluminum and titanium is used as the metal film 60.

After that, an impurity is doped into the second diffusion layer 22 by performing the heating treatment. Thereby, the second diffusion layer 22 becomes the n-type semiconductor. After the impurity is doped into the second diffusion layer 22, the metal film 60 is removed.

Next, the conductive film 43b is formed inside the insulating film 44 and on the bottom surface of the hole 42h, and the second conductive layer 43a is formed on the insulating layer 42. Thereby, the interconnection unit LI is formed as shown in FIG. 10. The respective conductive layers 43a, 43b are electrically connected to the channel body 20 via the second diffusion layer 22.

After that, for example, the replace process of the above electrode layers and respective selection gates is performed, the bit lines BL or the like are formed, and the semiconductor memory device of the embodiment is formed.

According to the embodiment, the channel body 20 using the oxide semiconductor is formed as well as the embodiments described above. Thereby, when the thickness of the channel body 20 is thinned, it becomes possible to suppress the decrease of the operation speed.

Furthermore, the first diffusion layer 21 using the nitride semiconductor doped with the n-type impurity is formed between the upper portion of the channel body 20 and the first conductive layer 41. Therefore, GIDL is likely to occur in the nitride semiconductor more than the oxide semiconductor. That is, it becomes possible to improve performance of the data erasing operation by using the nitride semiconductor as the first diffusion layer 21.

In addition to the above, the second diffusion layer 22 using the nitride semiconductor doped with the n-type impurity is formed between the channel body 20 and the interconnection unit LI. This makes it possible to improve the performance of the data erasing operation as well as the first diffusion layer 21 described above.

According to the embodiment, it becomes possible to suppress the increase of the resistance associated with high integration of the memory cell.

The oxide semiconductor of each of the embodiments described above includes the oxynitride semiconductor. That is, the channel body 20 includes, for example, at least one of zinc oxide, aluminum oxide, gallium oxide, indium oxide, zinc oxynitride, aluminum oxynitride, gallium oxynitride and indium oxynitride.

The nitride semiconductor of the embodiments described above includes the oxynitride semiconductor. That is, for example, at least one of zinc nitride, aluminum nitride, gallium nitride, indium nitride, zinc oxynitride, aluminum oxynitride, gallium oxynitride and indium oxynitride is used as each of the first diffusion layer 21 and the second diffusion layer 22.

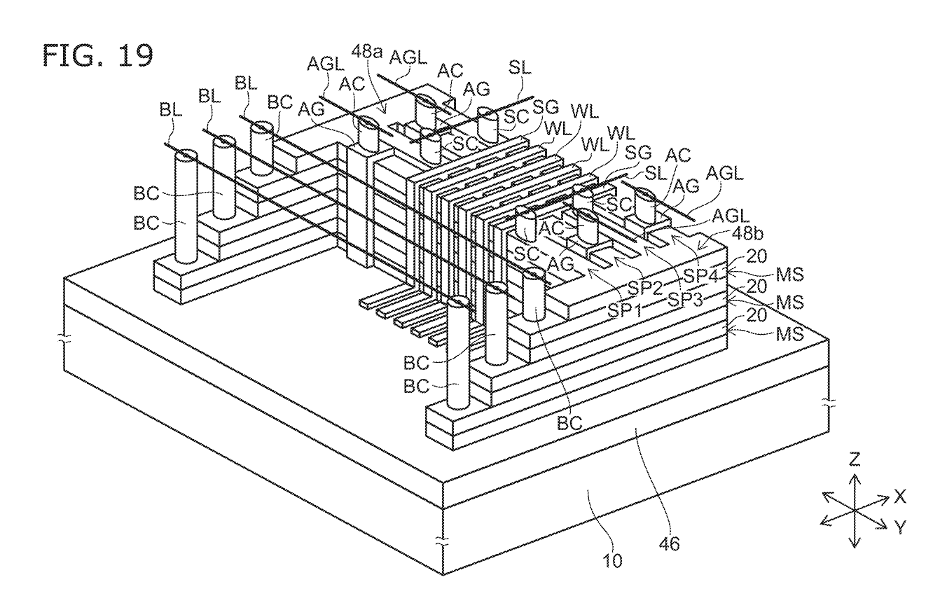

FIG. 19 is a schematic perspective view of the memory cell array of still another example of the semiconductor memory device of the embodiment.

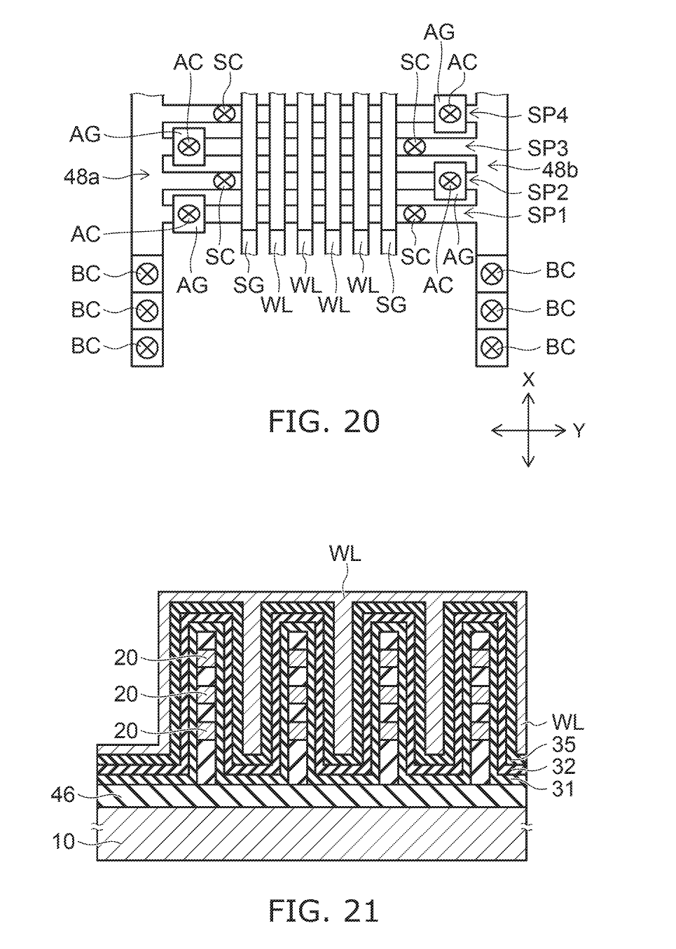

FIG. 20 is a schematic plan view of the memory cell array of still another example of the semiconductor memory device of the embodiment.

An insulating layer 46 is provided on the conductive layer 10. A plurality of fin type stacked structures SP (SP1, SP2, SP3, SP4) is provided on the insulating layer 46. The fin type stacked structures SP extend in Y-direction and are arranged in the X-direction.

The fin type stacked structures SP have a plurality of memory strings MS. The memory strings MS are separately provided in Z-direction each other. The number of the fin type stacked structures SP and the memory strings MS shown in the drawing are one example, and the number of the fin type stacked structures SP and the memory strings MS are arbitrary.

The fin type stacked structures SP are connected to one another at one end in the Y-direction by first portion 48a. The fin type stacked structures SP are connected to one another at the other end in the Y-direction by second portion 48b.

Both the first portion 48a and the second portion 48b have the same stack structure as the fin type stacked structures SP.

For example, the memory strings MS in odd fin type stacked structures SP1, SP3 among the fin type stacked structures SP use the first portion 48a as a drain region, and use the ends of the memory strings MS on the side of the second portion 48b as a source region.

For example, the memory strings MS in even fin type stacked structures SP2, SP4 among the fin type stacked structures SP use the second portion 48b as a drain region, and use the ends of the memory strings MS on the side of the first portion 48a as a source region.

That is, the memory strings MS in odd fin type stacked structures SP1, SP3 share the first portion 48a (drain region). The memory strings MS in even fin type stacked structures SP2, SP4 share the second portion 48b (drain region).

The source region of the memory strings MS in odd fin type stacked structures SP1, SP3 is insulated from the second portion 48b (drain region). The source region of the memory strings MS in even fin type stacked structures SP2, SP4 is insulated from the first portion 48a (drain region).

Each of the memory strings MS includes a plurality of memory cells, a source side selection transistor, a drain side selection transistor, and an assist gate transistor. The plurality of memory cells is connected in series in the Y-direction. The source side selection transistor is provided on the source side of the memory cells. The drain side selection transistor is provided on the drain side of the memory cells. The assist gate transistor is provided between the drain side selection transistor and the first portion 48a or the second portion 48b.

The plurality of the memory cells includes the semiconductor body 20 (channel body) and a stacked gate structure. The stacked gate structure is provided on the side surface of the semiconductor body 20 in the Y-direction.

As shown in FIG. 21, the stacked gate structure includes a tunnel insulating film 31 (gate insulating film), a block insulating film 35, a charge storage film 32, and an electrode layer WL. The number of the memory cells to constitute one memory strings MS are arbitrary.

Similarly to the memory cells, the drain side selection transistor and the source side selection transistor each includes the semiconductor body 20 and the stacked gate structure. Then, the stacked gate structure includes a selection gate SG.

The drain side selection transistor and the source side selection transistor may be different in structure from the memory cells. For example, each of these transistors may have a metal/insulator/semiconductor (MIS) structure that includes a gate insulating layer and a selection gate electrode provided on the gate insulating layer.

Similarly to the memory cells, the assist gate transistor also includes the semiconductor body 20 and the stacked gate structure. The assist gate transistor may be different in structure from the memory cells. For example, the assist gate transistor may have a MIS structure that includes a gate insulating layer and an assist gate electrode AG.

A plurality of assist gate electrodes AG is electrically isolated from one another. The assist gate electrodes AG are connected to assist gate lines AGL via contact plugs AC. This allows the assist gate transistor to have a function of selecting one of the fin type stacked structures SP.

More specifically, the ends of the first portion 48a and the second portion 48b in the X-direction, for example, have a staircase structure. Thus, the plurality of upper surfaces of the semiconductor bodies 20 is exposed. Parts of the semiconductor bodies 20 that expose their upper surfaces are bit line contact areas where the semiconductor bodies 20 are independently connected to bit lines BL via contact plugs BC respectively.

Therefore, one of the fin type stacked structures SP can be selected by use of the assist gate transistor, and reading/writing/erasing can be performed in the memory strings MS of the selected one fin type tacked structure SP.

The memory strings MS use the semiconductor bodies 20 as channels. Here, as one memory string MS uses one semiconductor body 20, increasing the number of semiconductor body 20 that constitutes one fin type stacked structure SP to increase the number of memory strings is preferable to higher integration.

The insulating film 31, the charge storage film 32, the block insulating film 35, and the electrode layer WL are separated in the Y-direction in the memory cells, the drain side selection transistor, the source side selection transistor, and the assist gate transistor. The charge storage film 32 and the block insulating film 35 may be united (continuous) throughout the memory cell, the drain side selection transistor, the source side selection transistor, and the assist gate transistor.

For example, the assist gate transistors are provided at the ends of odd fin type stacked structures SP1, SP3. For example, the assist gate transistors are provided at the ends of even fin type stacked structures SP2, SP4. This makes it possible to reduce the pitch (or spaces) of the fin type stacked structures SP in the X-direction.

The source region of the memory strings MS includes impurity region (e.g. N-type diffusion layer) in the semiconductor bodies 20 of the memory cells on the side of the first portion 48a and the second portion 48b. Impurity region as the source region is the connected to source line SL via contact plug SC.

The source region of the memory strings MS is provided closer to the memory cells than a line that connects assist gate electrodes AG in the X-direction.

Also in the embodiment, the semiconductor body 20 includes the oxide semiconductor. This makes it possible to suppress the decrease of the operation speed when the thickness of the semiconductor body 20 is thinned.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1.-16. (canceled)

17. A method for manufacturing a semiconductor memory device, comprising:
forming a stacked body on a conductive layer;
forming a first hole piercing the stacked body and extending in a stacking direction of the stacked body;
forming a film on a side wall of the first hole, the film including a charge storage film;
forming a semiconductor body inside the film including the charge storage film, the semiconductor body including an oxide semiconductor;
forming a second hole piercing a bottom of the first hole and reaching the conductive layer; and
forming a conductive film inside the second hole and electrically connecting the semiconductor body to the conductive layer.

18. The method according to claim 17, wherein
the conductive film is formed inside the semiconductor body as well,
oxidizing the conductive film formed inside the semiconductor body, and
leaving the conductive film formed inside the second hole as a contact unit.

19. The method according to claim 17, wherein
the second hole is formed in a state covering a side wall of the semiconductor body with a mask film.

20. The method according to claim 19, wherein
the mask film is an insulating film, and is removed before the forming the conductive film.

21. The method according to claim 17, wherein
the stacked body includes a plurality of electrode layers separately stacked each other.

22. A method for manufacturing a semiconductor memory device, comprising:
forming a stacked body on a conductive layer, the stacked body including a plurality of silicon including layers separately stacked each other;
forming a first hole piercing the stacked body and extending in a stacking direction of the stacked body;
forming a film on a side wall of the first hole, the film including a charge storage film;
forming a semiconductor body inside the film including the charge storage film, the semiconductor body including an oxide semiconductor;
forming a second hole piercing a bottom of the first hole and reaching the conductive layer; and
forming a conductive film inside the second hole and electrically connecting the semiconductor body to the conductive layer.

23. The method according to claim 22, wherein
the conductive film is formed inside the semiconductor body as well,
oxidizing the conductive film formed inside the semiconductor body, and
leaving the conductive film formed inside the second hole as a contact unit.

24. The method according to claim 22, wherein
the second hole is formed in a state covering a side wall of the semiconductor body with a mask film.

25. The method according to claim 24, wherein
the mask film is an insulating film, and is removed before the forming the conductive film.
